(19) United States
(12) Patent Application Publication
(10) Pub. No.: US 2018/0031930 A1
(43) Pub. Date: Feb. 1, 2018

(54) PIXEL UNIT AND ARRAY SUBSTRATE

(71) Applicant: Shenzhen China Star Optoelectronics Technology Co., Ltd., Shenzhen, Guangdong (CN)

(72) Inventor: Xiaowen LV, Shenzhen, Guangdong (CN)

(73) Assignee: Shenzhen China Star Optoelectronics Technology Co., Ltd., Shenzhen, Guangdong (CN)

(21) Appl. No.: 14/913,999

(22) PCT Filed: Dec. 30, 2015
(86) PCT No.: PCT/CN2015/099709

§ 371 Date: Feb. 24, 2016

(30) Foreign Application Priority Data
Dec. 21, 2015 (CN) 201510966877.0

(51) Int. Cl. G02F 1/1362; G09G 3/36; G02F 1/1333; H01L 27/12; H01L 23/64

(52) U.S. Cl. CPC G02F 1/136213; H01L 27/1255; H01L 23/642; G02F 1/133345; G09G 3/3607; H01L 28/75

(57) ABSTRACT

The present disclosure discloses a pixel unit and an array substrate, the pixel unit includes: a thin film transistor, and a storage capacitor electrically connected to the thin film transistor, the storage capacitor includes a first metal layer and a second metal layer disposed opposite to the first metal layer, a concave-convex pattern is provided on a surface of the first metal layer facing to the second metal layer. It is capable of effectively improving the aperture ratio of the liquid crystal display device, under the premise that the resolution of which is guaranteed.

### FIELD OF THE INVENTION

The present disclosure relates to the technical field of liquid crystal display, and in particular it relates to a pixel unit and an array substrate.

### BACKGROUND OF THE INVENTION

As the flat-display panels represented by liquid crystal device (LCD) and organic light emitting diode (OLED) are developing toward large size and high resolution, thin film transistor (TFT) has also been widespread concern since it is used as the core component of the flat-display panels. In the prior arts, the commonly used thin film transistors include amorphous silicon thin film transistor and oxide thin film transistor, wherein the oxide thin film transistor is widely applied because of its advantages, such as high carrier mobility, and no substantial changes to the existing LCD panel production line when applied.

While the liquid crystal display device is widely used, the resolution requirement of the liquid crystal display image to the users is higher and higher, in order to ensure high resolution, a sufficient potential of the TFT is required during display, therefore, in the production process of the display device, a storage capacitor is provided in the pixel unit for ensuring the potential.

However, the storage capacitor is generally made by sandwiching an insulating layer between two metal electrodes, since the metal electrodes are opaque, the aperture ratio of the display device is therefore reduced, affecting the display effect.

### SUMMARY OF THE INVENTION

The objective of the present disclosure is providing a pixel unit and an array substrate, which are capable of effectively improving the aperture ratio of a liquid crystal display device, under the premise that the resolution of which is guaranteed.

In order to solve the above problem, the present disclosure provides a technical solution of: providing a pixel unit, which comprises: a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer; the concave-convex pattern is a grid structure formed by providing grooves on the surface of the first metal layer.

Wherein, the concave-convex pattern is formed by treating the first metal layer with at least one of embossing, laser machining, or photolithography process.

Wherein, an insulating layer is sandwiched between the first metal layer and the second metal layer.

Wherein, the pixel unit further comprises a pixel electrode, the pixel electrode is connected to the storage capacitor in parallel.

Wherein, the thin film transistor is an oxide thin film transistor.

In order to solve the above problem, the present disclosure provides another technical solution of: providing a pixel unit, which comprises: a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer.

Wherein, the concave-convex pattern is formed by providing grooves on the surface of the first metal layer.

Wherein, the concave-convex pattern is formed by treating the first metal layer with at least one of embossing, laser machining, or photolithography process.

Wherein, the concave-convex pattern comprises a grid structure.

Wherein, an insulating layer is sandwiched between the first metal layer and the second metal layer.

Wherein, the pixel unit further comprises a pixel electrode, the pixel electrode is connected to the storage capacitor in parallel.

Wherein, the thin film transistor is an oxide thin film transistor.

In order to solve the above problem, the present disclosure provides yet another technical solution of: providing an array substrate, which comprises: a plurality of pixel units composed of a plurality of scan lines and a plurality of data lines intersecting with each other, the pixel unit comprises a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer.

Wherein, the concave-convex pattern is formed by providing grooves on the surface of the first metal layer.

Wherein, the concave-convex pattern is formed by treating the first metal layer with at least one of embossing, laser machining, or photolithography process.

Wherein, the concave-convex pattern comprises a grid structure.

Wherein, an insulating layer is sandwiched between the first metal layer and the second metal layer.

Wherein, the pixel unit further comprises a pixel electrode, the pixel electrode is connected to the storage capacitor in parallel.

Wherein, the thin film transistor is an oxide thin film transistor.

The beneficial effects of the present disclosure are: apart from the existing prior arts, the pixel unit of the present embodiment comprises a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer. The concave-convex pattern of the first metal layer increases the enfilade area of the first metal layer and the second metal layer which are disposed on two sides of the storage capacitor, and further increases a capacity of the storage capacitor. Thus, it is capable of reducing the physical size of the storage capacitor, without changing or even increasing the capacity of the storage capacitor, the aperture ratio of the liquid crystal display device is therefore increased, and the display image of the liquid crystal display device is improved.

### BRIEF DESCRIPTION OF THE DRAWINGS

FIG. 1 is a schematic diagram showing a cross-section of a pixel unit according to a preferred embodiment of the present disclosure.

FIG. 2 is a schematic diagram of a storage capacitor according to a preferred embodiment of the present disclosure.

FIG. 3 is a schematic diagram showing a plane view of a first metal layer of a storage capacitor according to a preferred embodiment of the present disclosure.

FIG. 4 is a schematic diagram of an array substrate according to a preferred embodiment of the present disclosure.

### DETAILED DESCRIPTION OF THE PREFERRED EMBODIMENTS

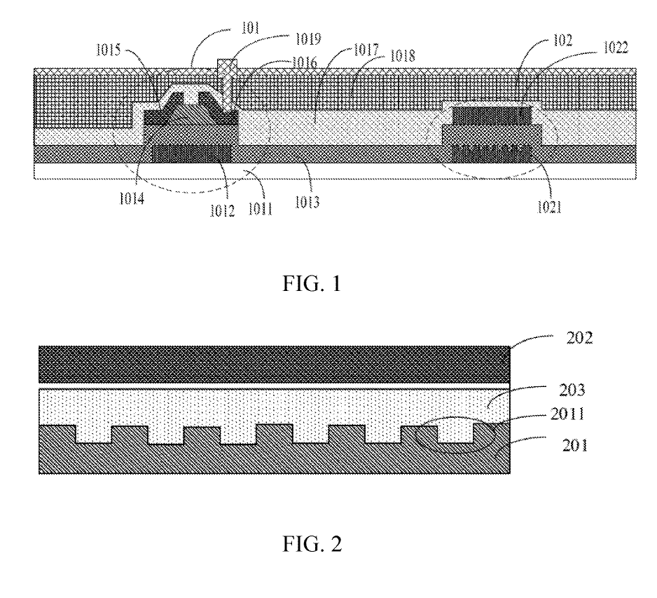

Please refer to FIG. 1, which is a schematic diagram showing a cross-section of a pixel unit according to a preferred embodiment of the present disclosure. As shown in FIG. 1, the pixel unit of the present disclosure comprises a thin film transistor 101, and a storage capacitor 102 electrically connected to the thin film transistor 101, wherein the storage capacitor 102 comprises a first metal layer 1021 and a second metal layer 1022 disposed opposite to the first metal layer, the thin film transistor 101 can be an oxide thin film transistor, or other types of transistors as long as they carry a turn-on function, the types of the transistors are not limited herein.

As shown in FIG. 1, the thin film transistor 101 comprises a gate 1012 disposed on a glass substrate 1011, an insulating layer 1013 formed on the gate 1012, an active layer 1014 disposed above the insulating layer 1013, and also comprises a source 1015 and a drain 1016 that are separated by a channel which exposing a partial active layer 1014 and being disposed at two sides of the active layer 1014. The surface of pixel electrode is further disposed with a passivation layer 1017, an overcoat layer 1018, and a touch electrode 1019 used for electrically connected to the storage capacitor 102.

Furthermore, the pixel unit further comprises a pixel electrode (not shown), the pixel electrode and the storage capacitor are electrically connected to the drain 1016 of the thin film transistor 101 via the touch electrode, the gate 1012 of the thin film transistor 101 is electrically connected to the scan line, the scan line provides a control signal to the thin film transistor 101, the source 1015 of the thin film transistor 101 is electrically connected to the data line, the data line provides a driving signal to the pixel unit. Particularly, when the thin film transistor 101 is conducted to an electrical signal, a charging voltage is provided to the storage capacitor 102, while a working voltage is provided to the pixel electrode. The storage capacitor stores charges, so as to supply a required potential for the pixel electrode when the thin film transistor 101 is off.

In order to provide a sufficient voltage to the pixel electrode, furthermore, a concave-convex pattern is provided on a surface of the first metal layer 1021 facing to the second metal layer 1022. Particularly, as shown in FIG. 2, which is a schematic diagram of a storage capacitor, a concave-convex pattern 2011 is provided on a surface of the first metal layer 1021 facing to the second metal layer 1022.

Furthermore, an insulating layer 203 is sandwiched between the first metal layer 201 and the second metal layer 202, the insulating layer 203 comprises inorganic oxides, such as silicon dioxide, or other insulating materials which are not limited herein.

Particularly, when the surface of the first metal layer 201 is disposed with the concave-convex pattern, it is able to effectively increase a relative enfilade area of the electrodes that form the storage capacitor. According to the capacitance formula, C=εS/(4 κ πd), wherein, ε, κ, π are both constant, S is an enfilade area of the first metal layer 401 and the second metal layer 402, d is a relative distance between the first metal layer 401 and the second metal layer 402. In the condition that the relative distance d remains unchanged, the larger the enfilade area, the greater is the capacity of the storage capacitor.

Therefore, providing the undulating concave-convex pattern on the surface of the first metal layer 201, by increasing the enfilade area of the first metal layer 401 and the second metal layer 402, the capacity of the storage capacitor can be increased without changing the volume of the storage capacitor of the original thin film transistor.

Furthermore, based on the above technical solution, it is capable of reducing the area occupied by the storage capacitor, and increasing the aperture ratio of the liquid crystal display device.

Wherein, the concave-convex pattern can be formed by treating the first metal layer with at least one of embossing, laser machining, or photolithography process, so as to form undulating grooves on the surface of the first metal layer 201, different shapes of the concave-convex patterns can therefore be formed, and the surface area of the first metal layer 201 is increased.

Wherein, the embossing process is placing a sheet material between an upper mold and a lower mold, making changes in material thickness under pressure effect, and filling the sheet material into the mold cavity and mold core having undulating fine lines, so as to obtain bulging characters or patterns on the surface of working products. Laser machining is a process by laser engraving various concave-convex patterns on the surface of the first metal layer. Photolithography process refers to a process by removing specific parts on the surface of the first metal layer, and leaving uneven patterns on the first metal layer. In the present embodiment, as long as the undulating concave-convex pattern can be formed on the surface of the first metal layer 201, the concave-convex pattern forming processes are not limited herein.

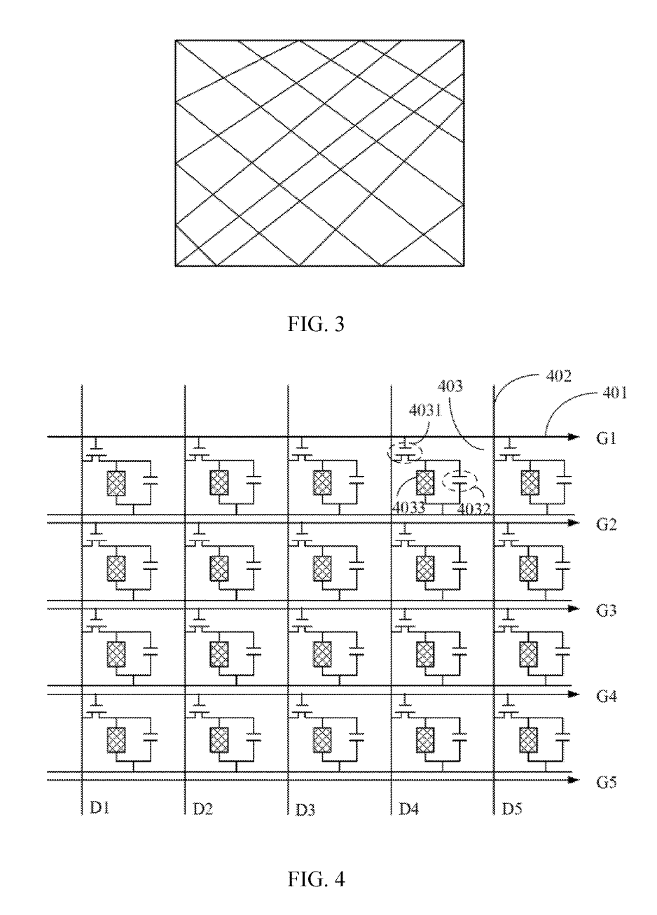

The concave-convex pattern is not limited by specific forms, such as a grid structure as shown in FIG. 3, in other embodiments, the concave-convex pattern can be any animal shape, specific Chinese characters, and so on, as long as it is capable of increasing the relative surface area of the first metal layer.

In another embodiment, the first metal layer 201 can also compose a storage capacitor with the pixel electrode of the thin film transistor, that is not limited herein.

Apart from the existing prior arts, the pixel unit of the present embodiment comprises a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer. The concave-convex pattern of the first metal layer increases the enfilade area of the first metal layer and the second metal layer which are disposed on two sides of the storage capacitor, and further increases a capacity of the storage capacitor. Thus, it is capable of reducing the physical size of the storage capacitor, without changing or even increasing the capacity of the storage capacitor, the aperture ratio of the liquid crystal display device is therefore increased, and the display image of the liquid crystal display device is improved.

Please refer to FIG. 4, which is a schematic diagram of an array substrate according to a preferred embodiment of the present disclosure. The array substrate of the present embodiment comprises a plurality of scan lines 401 and data lines 402, and a plurality pixel units composed of the plurality of scan lines and data lines intersecting with each other, each of the pixel units comprises a thin film transistor 4031, a storage capacitor 4032 electrically connected to the thin film transistor 4031, and a pixel electrode 4033 connected to the storage capacitor 4032 in parallel. Wherein, the thin film transistor 4031 comprises an oxide thin film transistor, a gate of the thin film transistor 4031 is connected to the scan line 401 for receiving a scanning control signal transmitted from the scan line 401, a source of the thin film transistor 4031 is connected to the data line 402 for receiving a data signal transmitted from the data line 402, a drain of the thin film transistor 4031 is connected to the storage capacitor 4032 and the pixel electrode 4033.

When the thin film transistor 4031 is conducted to an electrical signal, a charging voltage is provided to the storage capacitor 4032, while a working voltage is provided to the pixel electrode 4033. The storage capacitor stores charges, so as to supply a required potential for the pixel electrode 4033 when the thin film transistor 4031 is off.

Furthermore, the storage capacitor 4032 comprises a first metal layer and a second metal layer disposed opposite to each other. In order to provide a sufficient voltage to the pixel electrode 4033, furthermore, a concave-convex pattern is provided on a surface of the first metal layer facing to the second metal layer.

Particularly, the concave-convex pattern is not limited by specific forms, such as a grid structure, in other embodiments, the concave-convex pattern can be any animal shape, specific Chinese characters, and so on, as long as it is capable of increasing the relative surface area of the first metal layer.

Furthermore, an insulating layer is sandwiched between the first metal layer and the second metal layer, the insulating layer comprises inorganic oxides, such as silicon dioxide, or other insulating materials which are not limited herein.

Particularly, when the surface of the first metal layer is disposed with the concave-convex pattern, it is able to effectively increase a relative enfilade area of the electrodes that form the storage capacitor. According to the capacitance formula, C=εS/(4 κ π d), wherein, ε, κ, π are both constant, S is an enfilade area of the first metal layer 401 and the second metal layer 402, d is a relative distance between the first metal layer 401 and the second metal layer 402. In the condition that the relative distance d remains unchanged, the larger the enfilade area, the greater is the capacity of the storage capacitor.

Therefore, providing the undulating concave-convex pattern on the surface of the first metal layer, by increasing the enfilade area of the first metal layer and the second metal layer, the capacity of the storage capacitor can be increased without changing the volume of the storage capacitor of the original thin film transistor.

Furthermore, based on the above technical solution, it is capable of reducing the area occupied by the storage capacitor, and increasing the aperture ratio of the liquid crystal display device.

Wherein, the concave-convex pattern can be formed by treating the first metal layer with at least one of embossing, laser machining, or photolithography process, so as to form undulating grooves on the surface of the first metal layer, different shapes of the concave-convex patterns can therefore be formed, and the surface area of the first metal layer is increased.

Wherein, the embossing process is placing a sheet material between an upper mold and a lower mold, making changes in material thickness under pressure effect, and filling the sheet material into the mold cavity and mold core having undulating fine lines, so as to obtain bulging characters or patterns on the surface of working products. Laser machining is a process by laser engraving various concave-convex patterns on the surface of the first metal layer. Photolithography process refers to a process by removing specific parts on the surface of the first metal layer, and leaving uneven patterns on the first metal layer. In the present embodiment, as long as the undulating concave-convex pattern can be formed on the surface of the first metal layer, the concave-convex pattern forming processes are not limited herein.

In another embodiment, the first metal layer can also compose a storage capacitor with the pixel electrode of the thin film transistor, that is not limited herein.

Apart from the existing prior arts, the pixel unit of the present embodiment comprises a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer. The concave-convex pattern of the first metal layer increases the enfilade area of the first metal layer and the second metal layer which are disposed on two sides of the storage capacitor, and further increases a capacity of the storage capacitor. Thus, it is capable of reducing the physical size of the storage capacitor, without changing or even increasing the capacity of the storage capacitor, the aperture ratio of the liquid crystal display device is therefore increased, and the display image of the liquid crystal display device is improved.

Besides, the present disclosure further provides a liquid crystal display device, which comprises an array substrate as described in any one of the above embodiments, a color filter substrate, and liquid crystal cells sandwiched between the color filter substrate and the array substrate. The liquid crystal display device applies similar technical solutions as described above, which will not repeat herein.

The embodiments were chosen and described in order to explain the principles of the disclosure and their practical application so as to activate others skilled in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A pixel unit, which comprises:
a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer; the concave-convex pattern is a grid structure formed by providing grooves on the surface of the first metal layer.

2. The pixel unit as claimed in claim 1, wherein the concave-convex pattern is formed by treating the first metal layer with at least one of embossing, laser machining, or photolithography process.

3. The pixel unit as claimed in claim 1, wherein an insulating layer is sandwiched between the first metal layer and the second metal layer.

4. The pixel unit as claimed in claim 1, wherein the pixel unit further comprises a pixel electrode, the pixel electrode is connected to the storage capacitor in parallel.

5. The pixel unit as claimed in claim 1, wherein the thin film transistor is an oxide thin film transistor.

6. A pixel unit, which comprises:
a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer.

7. The pixel unit as claimed in claim 6, wherein the concave-convex pattern is formed by providing grooves on the surface of the first metal layer.

8. The pixel unit as claimed in claim 6, wherein the concave-convex pattern is formed by treating the first metal layer with at least one of embossing, laser machining, or photolithography process.

9. The pixel unit as claimed in claim 6, wherein the concave-convex pattern comprises a grid structure.

10. The pixel unit as claimed in claim 6, wherein an insulating layer is sandwiched between the first metal layer and the second metal layer.

11. The pixel unit as claimed in claim 6, wherein the pixel unit further comprises a pixel electrode, the pixel electrode is connected to the storage capacitor in parallel.

12. The pixel unit as claimed in claim 6, wherein the thin film transistor is an oxide thin film transistor.

13. An array substrate, which comprises a plurality of pixel units composed of a plurality of scan lines and a plurality of data lines intersecting with each other, wherein the pixel unit comprises a thin film transistor, and a storage capacitor electrically connected to the thin film transistor, the storage capacitor comprises a first metal layer and a second metal layer disposed opposite to the first metal layer, a concave-convex pattern is provided on a surface of the first metal layer facing to the second metal layer.

14. The array substrate as claimed in claim 13, wherein the concave-convex pattern is formed by providing grooves on the surface of the first metal layer.

15. The array substrate as claimed in claim 13, wherein the concave-convex pattern is formed by treating the first metal layer with at least one of embossing, laser machining, or photolithography process.

16. The array substrate as claimed in claim 13, wherein the concave-convex pattern comprises a grid structure.

17. The array substrate as claimed in claim 13, wherein an insulating layer is sandwiched between the first metal layer and the second metal layer.

18. The array substrate as claimed in claim 13, wherein the pixel unit further comprises a pixel electrode, the pixel electrode is connected to the storage capacitor in parallel.

19. The array substrate as claimed in claim 13, wherein the thin film transistor is an oxide thin film transistor.
